(19) United States
(12) Patent Application Publication
(10) Pub. No.: US 2008/0280414 A1
(43) Pub. Date: Nov. 13, 2008

(54) Systems and Methods for Fabricating Vertical Bipolar Devices

(75) Inventor: Rownak Jyoti Zaman, Austin, TX (US)

Correspondence Address: FULBRIGHT & JAWORSKI L.L.P., 600 CONGRESS AVE., SUITE 2400, AUSTIN, TX, 78701, US

(73) Assignee: ADVANCED TECHNOLOGY DEVELOPMENT FACILITY, INC.

(21) Appl. No.: 11/745,214

(22) Filed: May 7, 2007

(51) Int. Cl. H01L 21/331

(52) U.S. Cl. 438/378; 257/E21.37

(57) ABSTRACT

Systems and methods for fabricating bipolar and/or biCMOS devices are described. A combination of bipolar fabrication steps and CMOS, and in particular, SOI fabrication steps may be used. In one embodiment, a collector region and/or a base region of a bipolar device may be formed using a bipolar mask, and an emitter region may be defined by a CMOS mask.

### BACKGROUND OF THE INVENTION

1. Field of the Invention

The present invention relates generally to semiconductors and, more particularly, to systems and methods for fabricating bipolar and BiCMOS devices using silicon on insulator (SOI) processes.

2. Description of Related Art

Bipolar junction transistors (BJTs) are generally constructed from two n-p junctions disposed on a semiconductor crystal to form three distinct regions, an emitter (E) region, a base (B) region, and collector (C) region. Typically, there are two types or polarity of BJTs: NPN transistors (n-type emitter and collector with p-type base); and PNP transistors (p-type emitter and collector with n-type base).

There are several known semiconductor fabrication processes for forming the distinct regions of a bipolar junction transistor. The simplest structure is a planar architecture with the stacked NPN or PNP regions formed by successive implants onto a semiconductor substrate.

Recently, BJTs, and in particular, lateral BJTs, have been formed using a complementary metal oxide semiconductor (CMOS) process. The term “BiCMOS” refers to the integration of bipolar junction transistors and CMOS technology into a single device. In one respect, an NPN device may be formed from a NMOS transistor and a PNP transistor may be formed from a PMOS transistor. For each of the doped regions, a mask is used to define the area, such as a series of implant masks and ion implant masks are needed to form at least the emitter, base, and collector.

The present inventor has recognized that current BiCMOS fabrication techniques suffer from many disadvantages. For example, lateral bipolar transistors require precise masks, and therefore, overlap in the doped area and are difficult to align. Furthermore, lateral bipolar devices need a high definition mask to define the base area, and issues such as doping level control may affect the function of the device.

These referenced shortcomings are not intended to be exhaustive, but rather are among many recognized by the present inventor that tend to impair the effectiveness of previously known techniques concerning fabricating bipolar devices; however, those mentioned here are sufficient to demonstrate that the methodologies appearing in the art have not been satisfactory and that a significant need exists for the techniques described and claimed in this disclosure.

### SUMMARY OF THE INVENTION

The present invention comprises systems and methods for fabricating semiconductor devices including bipolar and BiCMOS devices using various steps of CMOS process flow. In one embodiment, a method for forming a vertical bipolar device is provided. The method includes proving a semiconductor substrate and depositing a semiconductor insulation layer on the substrate. In subsequent steps, a hardmask layer may be deposit on the insulation layer. A portion of the hardmask layer may be etched to expose a first portion of the insulation layer, the etched portion defined by a patter formed on a voltage threshold mask. Dopants may be implanted to the exposed first portion of the insulation to form a collector region.

Next, another portion of the hardmask layer may be etched to expose a second portion of the insulation layer, where the etching of the hardmask layer may be defined by a pattern formed on a bipolar mask. Dopants may be implanted into the second portion of the layer to form a base region coupled to the collector region. An emitter coupled to the base region may be defined with a CMOS epitaxial growth process.

The present invention also comprises a system and method for forming a bipolar device. The method includes forming a collector region of a bipolar device using a first bipolar mask. For example, a hardmask layer may be deposited on an insulation layer of a substrate. Next, the hardmask layer may be masked with a first bipolar device and may be etched to expose a first portion of the insulation layer of a substrate. Dopants may be implanted into the exposed first portion of the insulation layer to form the collector region.

The method also includes forming a base region coupled to the collector region. In one embodiment, a hardmask layer may be masked with a bipolar mask. Next, a portion of the hardmask layer may be etched to expose a portion of an underlying insulation layer. Dopants may be implanted into the exposed portion of the insulation layer to form the base region. An emitter region may subsequently be formed with a CMOS mask. In one embodiment, a source-drain implant step may be used.

The term “coupled” is defined as connected, although not necessarily directly, and not necessarily mechanically.

The terms “a” and “an” are defined as one or more unless this disclosure explicitly requires otherwise.

The term “substantially,” “about,” and its variations are defined as being largely but not necessarily wholly what is specified as understood by one of ordinary skill in the art, and in one non-limiting embodiment, the substantially refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE SEVERAL VIEWS OF THE DRAWING

The following drawings form part of the present specification and are included to further demonstrate certain aspects of the present invention. The invention may be better understood by reference to one or more of these drawings in combination with the detailed description of specific embodiments presented herein.

FIGS. 1-15 show fabrication steps for forming a BJT device in accordance with exemplary embodiments of the present invention;

FIG. 16 shows a layout of a BJT device in accordance with exemplary embodiments of the present invention; and

FIGS. 17-20 show cross-section views of BJT devices in accordance with exemplary embodiments of the present invention.

### DETAILED DESCRIPTION OF THE INVENTION

The invention and the various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to a person of ordinary skill in the art from this disclosure.

The present disclosure provides methods for the fabrication of a bipolar device in a field-effect transistor (FET) process flow. In particular, the present disclosure provides methods for fabricating vertical BJTs that are compatible with the next generation three dimension metal oxide semiconductor field effect transistor (MOSFET) fabrication on, for example, silicon on insulator (SOI) substrates or similar types of substrates with an insulator layer (e.g., silicon, silicon-germanium, gallium-arsenide, etc.). The masks used fabricating the bipolar devices are similar to the existing masks for CMOS fabrication, with the addition of, for example, a base epitaxial (EPI) region definition mask and an emitter-base and base-collector isolation mask for a specific integration. For non-EPI base devices, a mask for the epitaxial growth of silicon, silicon germanium, or other EPI growth may be needed in addition to the masks used in the CMOS fabrication process.

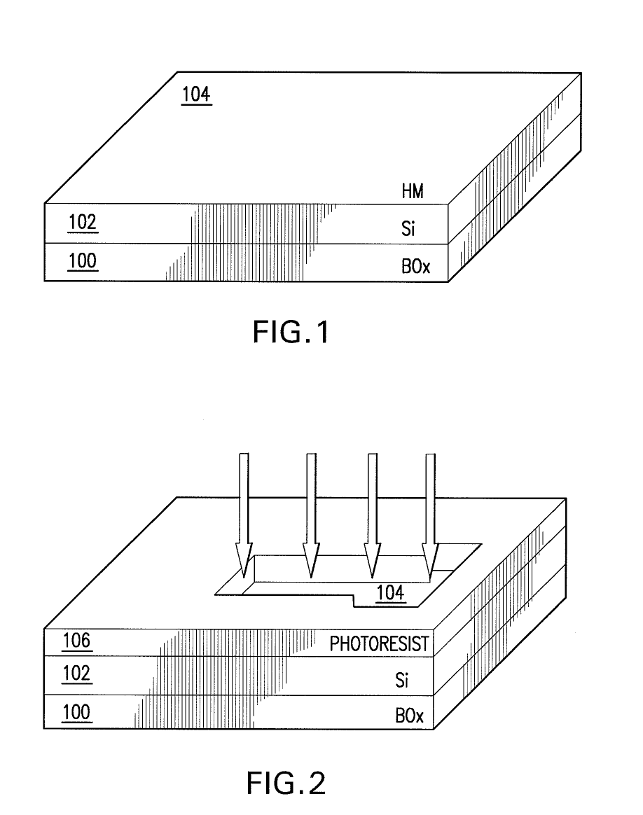

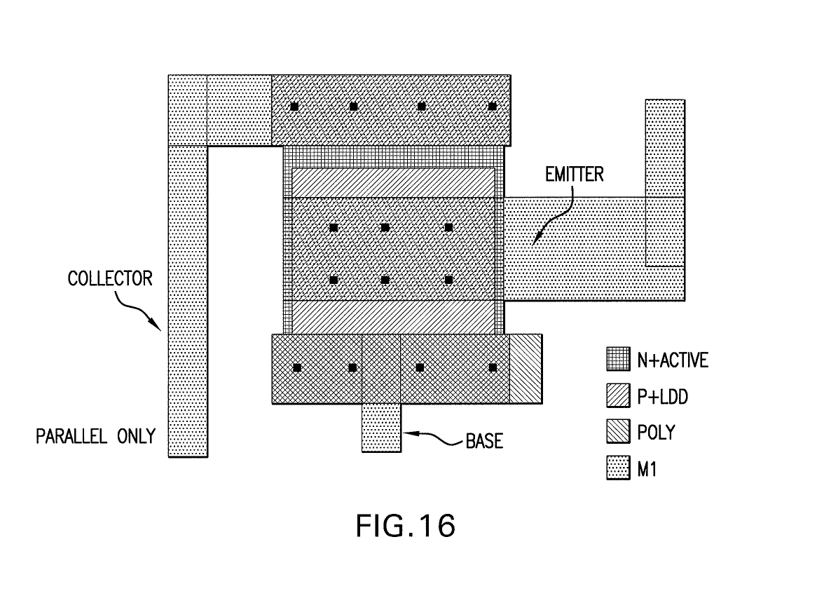

Referring to FIGS. 1 through 15, exemplary steps for fabricating a FIN-BJT are shown. A layout schematic of the FIN BJT is shown in FIG. 16. In one respect, the FIN-BJT may be compatible with process flows such as a tri gate process flow, a FINFET process flow, a Pi-gate process flow, omega gate process flow, or any MUGFET process flow. It is noted that the steps shown in FIGS. 1 through 15 are example steps, and that other typical processing sequencing may be used depending on the device design.

For an EPI based process on a SOI substrate, a hard mask or other suitable masks may be deposited on the silicon layer and may be used for the emitter/collector implant, as shown in FIG. 1. Hardmask layer 104 may include, for example, an oxide layer, a nitride layer, or other suitable compound layers known in the art. In alternative embodiments, for EPI process flows or other fabrication steps that do not need hardmask layer 104, an integration scheme may follow the CMOS process.

Next, a voltage threshold (V_{T}) implant mask may be used to mask an area for implant a dopant to form a collector region, which may define the effective collector area of the device as well as the contact for the collector, as shown in FIG. 2. For an NPN BJT transistor collector, a PMOS threshold adjust implant may be used. For a PNP BJT transistor collector, a NMOS threshold adjust implant may be used. For an emitter first process, a separate mask may bed used.

In one respect, the V_{T} implant mask may be used prior to a FIN etching process. During the V_{T} implants, the collector region of the FIN-BJT may be partially implanted. For an NPN transistor collector, a PMOS threshold implant may be used and for a PNP transistor collector, a NMOS threshold implant may be used. If the implant is not compatible, either V_{T} implant mask will have no openings during the implant process or the adjustments in the collector implant may be performed later. In this case, a collector mask, specific to the type of BJT transistor may be used where the mask may open up the collector area on the device and the collector area may be implanted or adjusted.

Alternatively, a collector area implant may be performed after a FIN etching process. In one respect, a specific V_{T} implant mask may be used depending on the type of BJT (NPN or PNP). V_{T} implant mask may be used to open-up the collector area of the FIN BJT. Hard mask 104 may be etched in areas where photoresist layer has been deposited and patterned and subsequently exposed by an electromagnetic source through the V_{T} implant mask. The exposed hard mask etch may be grown to define the base thickness of the FIN BJT to form selective EPI growth area.

As noted above, or devices that do not require a hard mask layer similar to layer 104, the thin mask that was deposited may be removed. After a FIN etching process, the V_{T} implants may be performed. In particular, the collector region of the FIN BJT may be implanted.

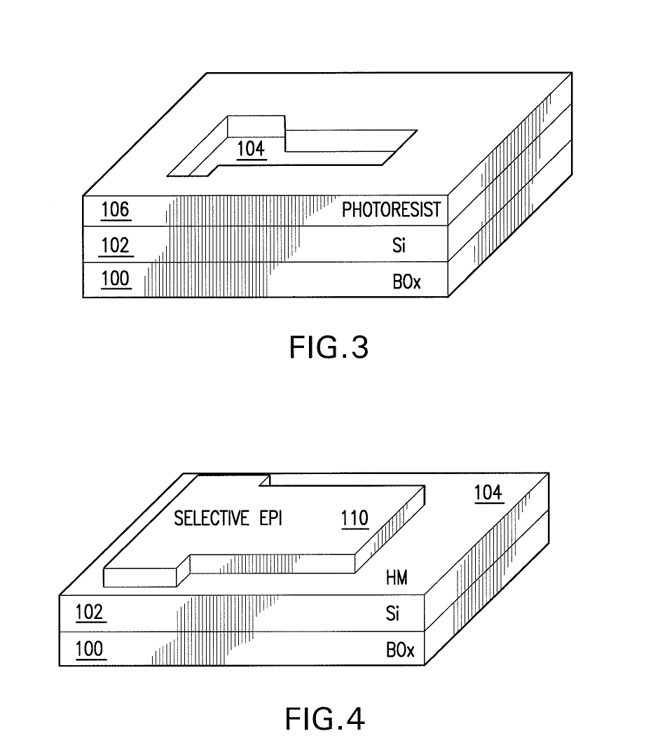

Next, the FIN BJT base area may be defined. Referring to FIG. 3, the mask used for the V_{T} implant may be used to etch hardmask 104 in the base region of the FIN BJT. The photoresist layer 106 may be subsequent removed using techniques known in the art. Next, an epitaxial process may begin to grow silicon/silicon germanium or other high mobility film to form a selective epi-layer 110, as shown in FIG. 4.

Alternatively, a high mobility film may be deposited prior to the epitaxial process. In one respect, the high mobility film may be deposited before the hard mask 104 and may subsequently be patterned using a mask (e.g., V_{T} implant mask) in areas except for the base region, as defined by photoresist layer 106. An optional implanting the base region may be done or may be postponed to during or after a light doped drain (LDD) implant.

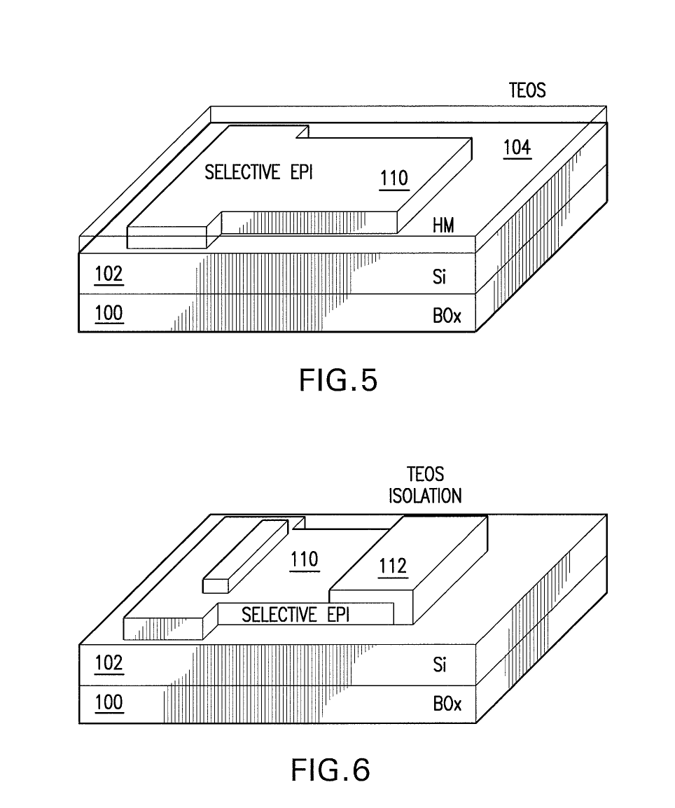

Thereafter, an isolation step may be performed. Referring to FIG. 5, a hard mask such as a TEOS or a film compatible with the film on hardmask 104, including, for example, a film compatible in temperature, etch selectivity, clean or any other fabrication requirements for process integration, may be deposited. Using a photoresist layer and an isolation mask, an isolation area for the FIN BJT may be formed. In one respect, a selective dry etch or a time etch for isolating “islands” may be performed for providing isolation between the collector-emitter. For a time etch, an wet etch step may be performed to substantially remove hardmask layer 104 and a portion of silicon layer 102, as shown in FIG. 6. After the isolation process, a CMOS process area may also cleared and ready for further processing.

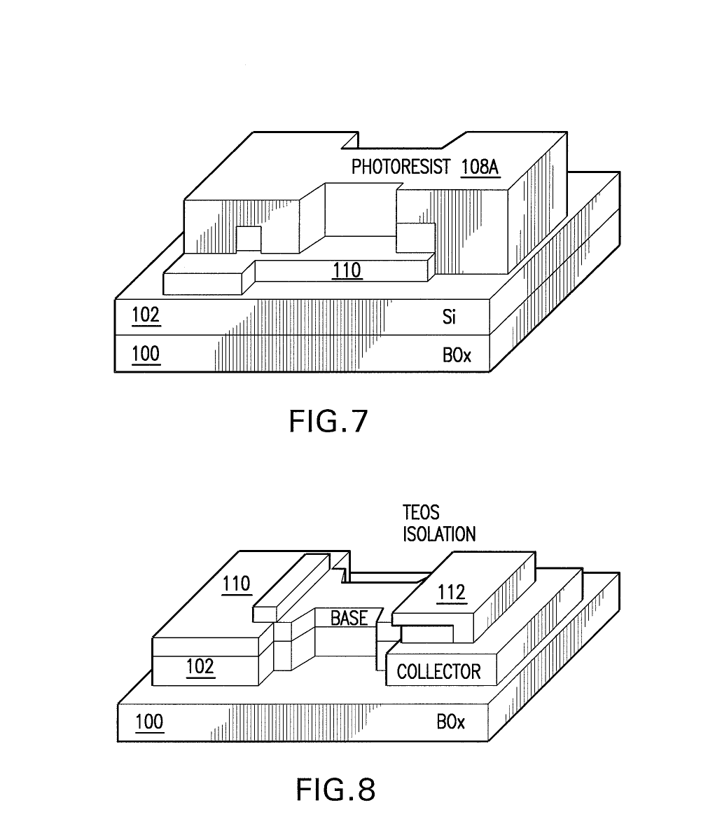

Next, the base and collector pattern of the FIN BJT using a CMOS process. In particular, a FIN lithography step, a FIN etch step, an ASH step, and clean step may be performed. During the FIN etch process, the base, and the collector shapes may be defined according to the details of a litho-mask. A photoresist layer 108A may be deposited on the resultant structure shown in FIG. 7 and may subsequently be patterned (as shown in FIG. 7). Electromagnetic radiation through the litho-mask, such as a LDD mask and a SD implant mask, may define the base and collector region of the FIN BJT, as shown in FIG. 8, where a portion of silicon layer 102 is etched.

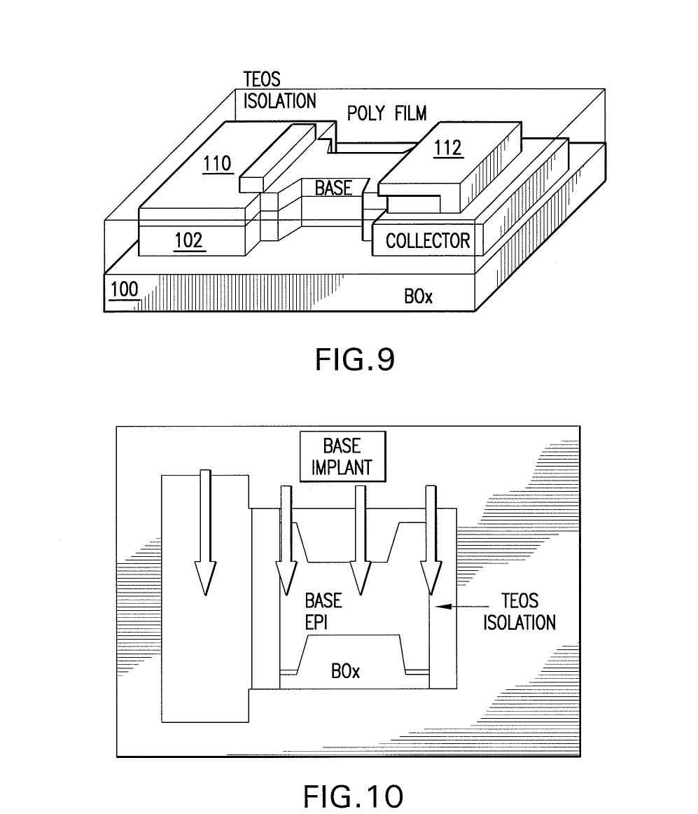

Referring to FIG. 9, a gate poly may be deposited on the resultant structure shown in FIG. 8. The gate poly (implanted or non-implanted) may be part of a CMOS gate process which does not affect the FIN BJT device. The gate poly may be subsequently etched using an etchant selective to the gate dielectric. The gate dielectric layer may protect the BJT silicon layer and may subsequently be removed during further fabrication process (e.g., epitaxial step).

Next, a base formation of the FIN BJT that has not been implanted is defined. If the process includes LDD implants, the NPN transistor base may be implanted during PLDD and the PNP transistor base may be implanted during NLDD. This is achievable due to the LDD dose being sufficient for FIN BJT base implant. Alternatively, a Halo process may be used for opposite species. In either LDD or Halo implants, the effective doping level may be calculated for sufficient base doping to increase the lifetime of the minority carrier as well as achieving lower gain.

In one respect, in the case of device optimization, LDD implant may be blocked at the FIN BJT region and base implant may be formed during the second use of the FIN BJT mask, similar to what is shown in FIG. 10. Alternatively, the base may be implanted after the EPI formation and before the isolation film is deposited, similar to what is shown in FIG. 3.

For higher gain target, the base of the FIN BJT transistor may not be open during the LDD process Halo implant process using the V_{T} implant mask, as shown in FIG. 10. This may allow the base area and depth to be control with desired tilt and twist angles, especially to implant sufficient dopants under the isolation between the connections and emitter area (described below).

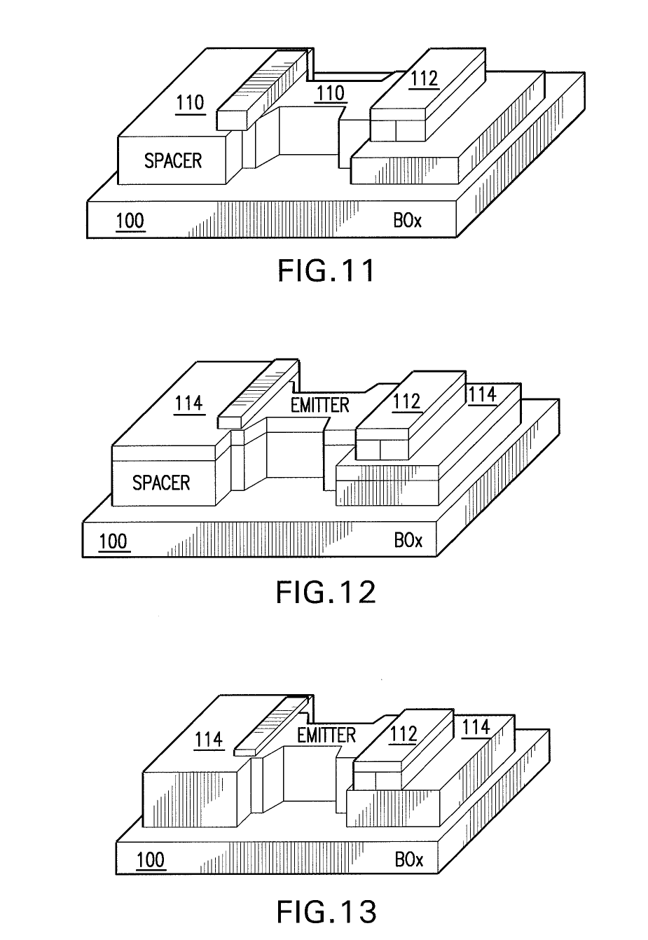

In the step shown in FIG. 11, a CMOS spacer process may further isolate the collector and the base contact region from the FIN device. The spacer may also be around the collector, base, and emitter area of the device.

Next, in the step shown in FIG. 12, the emitter is formed. A selective EPI growth for increasing the size of the source drain region in a CMOS structure may be used to form the selective EPI 114 on the base region of the FIN BJT. The details for selective EPI may be determined based on the requirement and compatibility of the process. The spacer formed in the step shown in FIG. 10 may form the EPI in the FIN area.

Alternatively, if the spacer is removed from the sidewall of the FINs body/source-drain region of the CMOS structure, the EPI 114 may grow in all three sides of the base area. In other respects where the step shown in FIG. 11 is omitted, the isolation island formed in the step shown in FIG. 8 may be used for the FIN BJT isolation, as shown in FIG. 12.

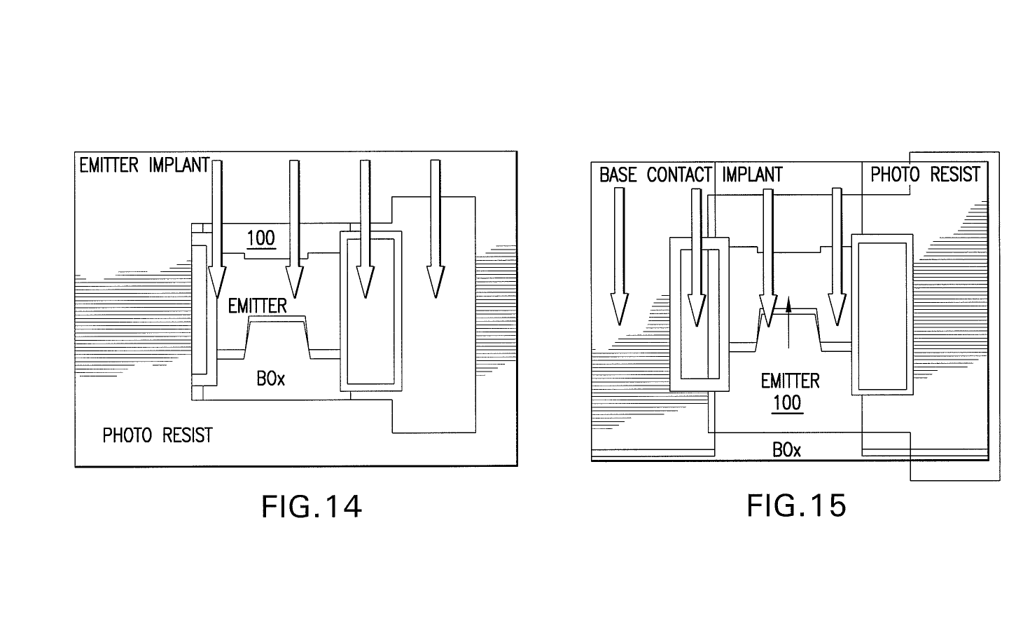

The emitter region may be implanted using the implant method for the source and drain in a CMOS device, as shown in FIG. 14. Similarly, the heavy collector contact and the base contact region may also be implanted using the similar CMOS process flow step as shown in FIGS. 14 and 15.

Thereafter, an anneal for the CMOS process flow may be used to activate the dopants for the FIN BJT. A silicidation process may follow to ease the contacts of the three terminals, as shown in FIG. 15.

It is noted that other CMOS process flow steps including, without limitation, interlayer dielectric (ILD), contact, metallization, and the like may also be used to fabricate the FIN BJT. Furthermore, other CMOS process flow may be used to fabricate the FIN BJT. For example, in an EPI based process, a CMOS MugFET process flow may be used to fabricate a FIN BJT. The fabrication may begin with the FIN BJT collector process, followed by the MugFET process flow. A hard mask layer (e.g., an oxide layer, a nitride layer, etc.) may be deposited. In one respect, the hard mask layer may have a thickness of about a few angstroms, although other thicknesses. The collector region of the FIN BJT may be defined and etched using a FIN BJT collector mask. Next, an EPI may be grown selectively. Then the usual MugFET process flow may be initiated with or without the hardmask. In one respect, the hardmask may be removed after the FIN formation and before the gate oxide deposition. Proper cleans and related process for integration may be added.

For non-EPI base process, the fabrication process may begin with a SOI thinning for MugFET may or may not define the FIN BJT collector. In one respect, a thin oxide having a thickness of about 45 Angstrom and nitride layer having a thickness of about 200 Angstroms may be deposited for the SOI thinning process. It is noted that the oxide film and nitride films may have a thickness of less than 45 Angstroms and 200 Angstroms, respectively. In general, the thickness of the films may depend on the tools capability, design process, or other fabrication parameters. One of ordinary skill would recognize that the thicknesses are exemplary, and other thicknesses may be used.

Next, the FIN BJT collector mask with a negative resist may hold the nitride-oxide film and the remainder of the wafer may receive a hardmask strip, similar to what is shown in FIG. 3. The hardmask of the FIN BJT may allow for selective oxidation at the CMOS and other area and may prevent silicon loss at the FIN BJT area. The nitride-oxide film may subsequently be removed. The remainder of the process flow may remain the same as described above.

It is noted that FIGS. 1-15 show example fabrication steps for forming a BJT device. The process steps may vary depending on, for example, the layout of the BJT device. In some embodiments, with special processing like strip of gate oxide (for CMOS process) and poly gate deposition, an emitter may be deposited and patterned. The emitter and collector may also be swapped, using, for example, special masks and implant conditions.

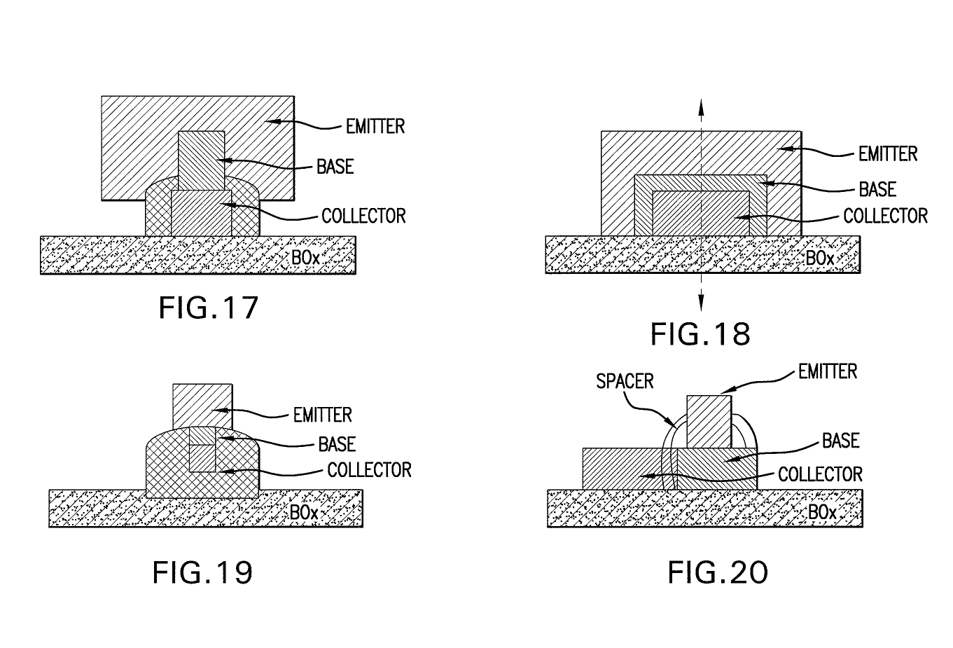

For example, referring to FIGS. 17 through 20, various cross sectional views of different BJTs are shown. A silicon and/or Epi may define the base and the collector or emitter for small FIN BJTs with precise implant. Subsequent, gate electrode deposition and pattern or selective epi growth (SEG) may define the emitter/collector.

The difference between the fabrication of the device shown in FIGS. 17 and 19 versus FIG. 20 is based on an implant energy causing device formation change and also cause performance change. For FIG. 18, a large bulk of material with SEG growth may be controlled by implant dose and energy for a thinner base.

All of the methods disclosed and claimed herein can be executed without undue experimentation in light of the present disclosure. While the methods of this disclosure may have been described in terms of preferred embodiments, it will be apparent to those of ordinary skill in the art that variations may be applied to the methods and in the steps or in the sequence of steps of the method described herein without departing from the concept, spirit and scope of the disclosure. All such similar substitutes and modifications apparent to those skilled in the art are deemed to be within the spirit, scope, and concept of the disclosure as defined by the appended claims.

1. A method comprising:
providing a semiconductor substrate;
depositing a semiconductor insulation layer on the semiconductor substrate;
depositing a hardmask layer on the semiconductor insulation layer;
etching a portion of the hardmask layer to expose a first portion of the semiconductor insulation layer, the etched portion of the hardmask defined by a pattern formed on a voltage threshold mask;
implanting dopants to the exposed first portion of the semiconductor insulation layer to form a collector region;
etching another portion of the hardmask layer to expose a second portion of the semiconductor insulation layer, the another portion of the hardmask layer defined by a pattern formed on a bipolar mask;
implanting dopants to the second portion of the semiconductor insulation layer to form a base region coupled to the collector region; and
defining an emitter region coupled to the base region with a CMOS epitaxial growth process.

2. The method of claim 1, further comprising forming an epitaxial growth on the etched second portion of the hardmask layer.

3. The method of claim 2, further comprising isolating the epitaxial growth.

4. The method of claim 3, the step of isolating the epitaxial growth comprising etching a portion of the epitaxial growth area with an isolation mask.

5. The method of claim 1, further comprising forming a base and collector pattern with a CMOS process.

6. The method of claim 5, the step of forming a base and collector pattern comprising etching a FIN with a CMOS litho-mask.

7. The method of claim 1, further comprising forming spacers for isolating the collector and base region.

8. The method of claim 1, the step of defining the emitter region further comprising doping the emitter region with a source-drain implant.

9. The method of claim 1, further comprising annealing the vertical bipolar device.

10. A method comprising:
forming a collector region of a bipolar device using a first bipolar mask;
forming a base region coupled to the collector region using a second bipolar mask; and
forming an emitter region of the bipolar device using a CMOS mask.

11. The method of claim 10, the step of forming the collector region comprises:
depositing a hardmask layer on a semiconductor insulation layer of a substrate;
masking the hardmask layer with the first bipolar mask;
etching a first portion of the hardmask layer based on the first bipolar mask to expose a first portion of the semiconductor insulation layer; and
implanting dopants to the exposed first portion of the semiconductor insulation layer to form the collector region.

12. The method of claim 10, the step of forming the base region comprising:
masking the hardmask layer with the second bipolar mask;
etching a second portion of the hardmask layer based on the second bipolar mask to expose a second portion of the semiconductor insulation layer; and
implanting dopants to the second portion of the semiconductor insulation layer for forming the base region.

13. The method of claim 10, the step of forming the emitter region further comprising doping the emitter region with a source-drain implant.
